(19) United States
(12) Patent Application Publication
(10) Pub. No.: US 2025/0160074 A1
(43) Pub. Date: May 15, 2025

(54) Electronic Device with a Display Cover Layer

(71) Applicant: Apple Inc., Cupertino, CA (US)

(72) Inventors: Wenzhong Liu, San Jose, CA (US); Avery P Yuen, Campbell, CA (US); Daming Xu, Santa Clara, CA (US); Jun Qi, San Jose, CA (US); Jungwook Park, Cupertino, CA (US); Masato Kuwabara, Tsukuba (JP); Meizi Jiao, San Jose, CA (US); Mingxia Gu, Campbell, CA (US); Mookyung Son, Cupertino, CA (US); Rasmi R Das, Sunnyvale, CA (US); Sebastian Knitter, San Francisco, CA (US); Victor H Yin, Cupertino, CA (US); Yu Wang, Santa Clara, CA (US); Zhenyue Luo, Campbell, CA (US); Zhijian Lu, San Jose, CA (US)

(21) Appl. No.: 18/890,511

(22) Filed: Sep. 19, 2024

Related U.S. Application Data
(60) Provisional application No. 63/599,270, filed on Nov. 15, 2023.

(51) Int. Cl. H01L 33/54

(52) U.S. Cl. CPC H10H 20/853

(57) ABSTRACT

An electronic device may include display pixels and a display cover layer. The display cover layer may be formed from a transparent material such as glass. The display cover layer may have a nanotextured upper surface to improve the optical and mechanical characteristics of the display cover layer. The nanotextured upper surface may include first and second different types of nanostructures. The first type of nanostructures may have a relatively low aspect ratio and a first average height. The second type of nanostructures may be elongated nanostructures with a relatively high aspect ratio and a second average height that is greater than the first average height.

This application claims the benefit of U.S. provisional patent application No. 63/599,270, filed Nov. 15, 2023, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels or a liquid crystal display (LCD) based on liquid crystal display pixels. An electronic device may include a display cover layer that is formed over the display.

It is within this context that the embodiments herein arise.

### SUMMARY

An electronic device comprising a display cover layer and display pixels that emit light through the display cover layer. The display cover layer may have an upper surface and the upper surface may include first protrusions of a first type that have a first spatial frequency and second protrusions of a second type that is different than the first type that have a second spatial frequency that is different than the first spatial frequency.

An electronic device may include a glass layer and display pixels that emit light through the glass layer. The glass layer may have an upper surface with a first plurality of surface features each having a respective aspect ratio that is less than 2:1 and a second plurality of surface features each having a respective aspect ratio that is greater than 4:1.

A glass layer may have first and second opposing sides. The glass layer may include a first plurality of protrusions on the first side, each one of the first plurality of protrusions having a respective height that is less than 200 nanometers, and a second plurality of protrusions on the first side, each one of the second plurality of protrusions having a respective height that is between 200 nanometers and 1 micron.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a cross-sectional side view of an illustrative electronic device with display pixels and a display cover layer in accordance with some embodiments.

FIG. 4 is a top view of an illustrative display cover layer with nanostructures in accordance with some embodiments.

FIG. 5 is a cross-sectional side view of the illustrative display cover layer of FIG. 4 in accordance with some embodiments.

FIG. 6 is a top view of an illustrative nanostructure from the display cover layer of FIGS. 4 and 5 in accordance with some embodiments.

FIG. 7 is a top view of an illustrative display cover layer with elongated nanostructures in accordance with some embodiments.

FIG. 8 is a cross-sectional side view of the illustrative display cover layer of FIG. 7 in accordance with some embodiments.

FIG. 9 is a top view of an illustrative elongated nanostructure from the display cover layer of FIGS. 7 and 8 in accordance with some embodiments.

FIG. 10 is a diagram showing how nanotexture with a first layout may be combined with nanotexture with a second layout to form an illustrative hybrid nanotexture with first and second different types of nanostructures in accordance with some embodiments.

FIG. 11 is a cross-sectional side view of an illustrative display cover layer with first and second different types of nanostructures in accordance with some embodiments.

### DETAILED DESCRIPTION

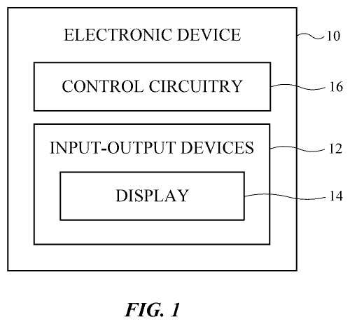

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user. As examples, electronic device 10 may be an augmented reality (AR) headset and/or virtual reality (VR) headset.

As shown in FIG. 1, electronic device 10 may include control circuitry 16 for supporting the operation of device 10. The control circuitry may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

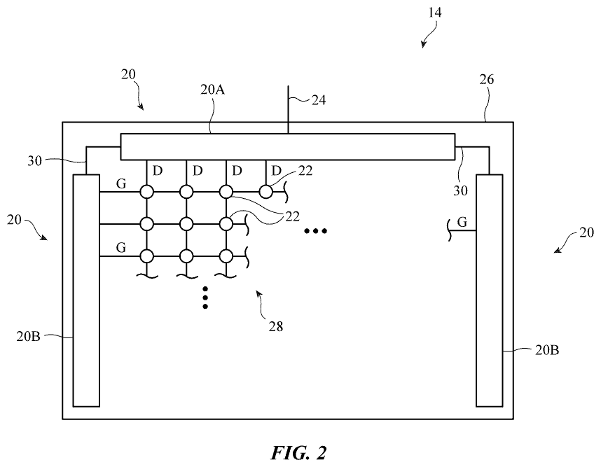

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

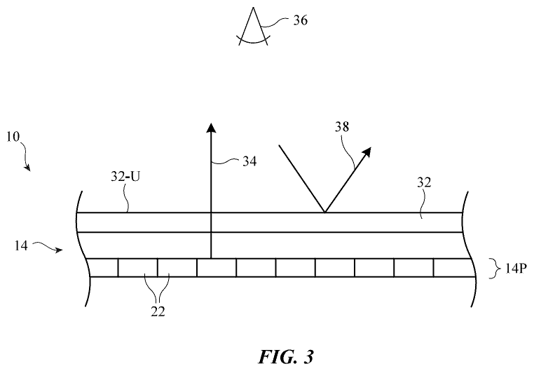

FIG. 3 is a cross-sectional side view of an illustrative electronic device 10 with a display. As shown in FIG. 3, the electronic device 10 may include a display panel 14P with pixels 22. The display panel 14P may be overlapped by a display cover layer 32. The display cover layer may be formed by a transparent material such as glass, plastic, or sapphire. The transparency of display cover layer 32 may be greater than 90%, greater than 95%, greater than 98%, etc. Display cover layer 32 may be considered part of display 14.

The display cover layer 32 may serve as a protective layer for display panel 14P to protect display panel 14P from damage during operation of electronic device. The display cover layer 32 may therefore desirably have a high strength (e.g., so that the display cover layer is robust to impacts). Pixels 22 emit light in direction 34 through display cover layer 32 towards viewer 36.

Additionally, the display cover layer 32 may have optical properties selected to improve the efficiency and aesthetic appearance of display 14. As one example, display cover layer 32 may have an upper surface that is textured to mitigate reflections of ambient light. As shown in FIG. 3, ambient light may follow path 38 and reflect off upper surface 32-U of display cover layer 32. These types of reflections may reduce contrast in display 14 and may therefore be undesirable.

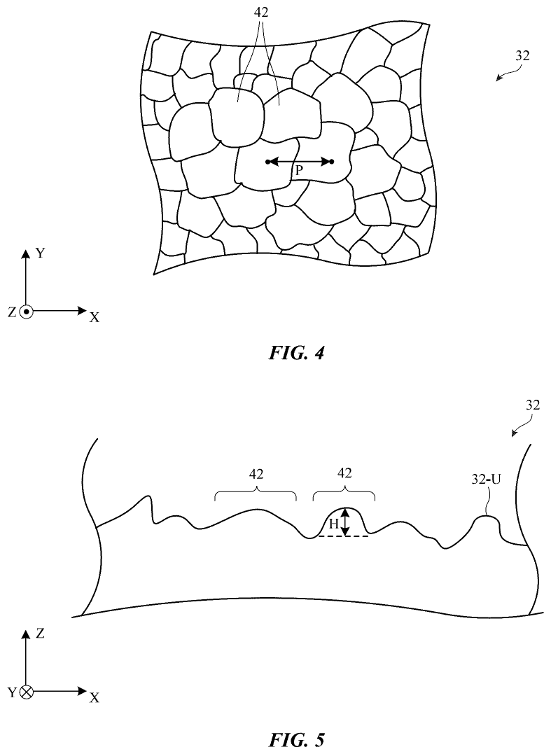

To improve the performance of display cover layer 32, upper surface 32-U may be modified to have nanotexture. A display cover layer with nanotexture may have a plurality of structures (e.g., nanostructures and/or microstructures) on the upper surface 32-U of the glass layer. Herein, protrusions or recesses with a dimension that is less than 1 micron may be referred to as nanostructures and protrusions or recesses with a dimension that is less than 1 millimeter may be referred to as microstructures). FIG. 4 is a top view of a display cover layer 32 with structures 42 (sometimes referred to as protrusions 42, surface features 42, nanostructures 42, microstructures 42, nanostructures and/or microstructures 42, etc.). In FIG. 4, nanostructures have footprints that are substantially circular (e.g., close to a 1:1 aspect ratio). These types of nanostructures may be referred to as circular nanostructures, pseudocircular nanostructures, etc.

As shown in FIG. 4, nanostructures 42 may be separated by a center-to-center pitch P. Pitch P may be equivalent to the distance between the geometric centers of adjacent nanostructures. The magnitude of pitch P may be, on average, greater than 1 micron, greater than 3 microns, greater than 5 microns, greater than 10 microns, greater than 20 microns, greater than 50 microns, less than 1 micron, less than 3 microns, less than 5 microns, less than 10 microns, less than 20 microns, less than 50 microns, etc. Each given pitch between adjacent nanostructures may also be greater than 1 micron, greater than 3 microns, greater than 5 microns, greater than 10 microns, greater than 20 microns, greater than 50 microns, less than 1 micron, less than 3 microns, less than 5 microns, less than 10 microns, less than 20 microns, less than 50 microns, etc.

FIG. 5 is a cross-sectional side view of the display cover layer of FIG. 4. As shown in FIG. 4, the upper surface 32-U has a plurality of protruding portions and recessed portions to define a non-linear nanotextured surface. In FIG. 5, nanostructures 42 are formed from protrusions. However, this example is merely illustrative and it should be understood that nanostructures 42 may also include recessed portions (sometimes referred to as depressions, craters, etc.) in display cover layer 32.

As shown in the cross-sectional side view of FIG. 5, the sloped sidewalls of each nanostructure 42 may have varying angles relative to the XY-plane. In general, the sloped sidewalls may have any desired angle(s) and the angle(s) may vary as a function of position in the X-direction and/or Y-direction.

FIG. 5 also shows how each nanostructure may have a corresponding height H. The height of each nanostructure may be at least 20 nanometers, at least 50 nanometers, at least 100 nanometers, at least 200 nanometers, at least 500 nanometers, less than 20 nanometers, less than 50 nanometers, less than 100 nanometers, less than 200 nanometers, less than 500 nanometers, between 50 nanometers and 200 nanometers, etc.

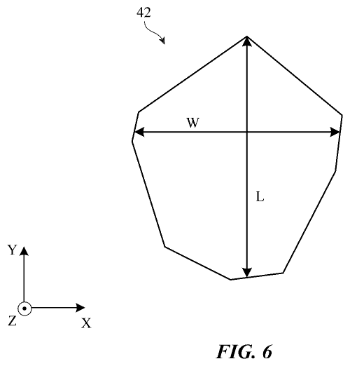

As shown in FIGS. 4 and 5, the nanostructures 42 may have irregular footprints. FIG. 6 is a top view of an illustrative nanostructure with an irregular footprint. The footprint may be characterized by a total width W and a total length L. The width W may refer to the total separation along the X-direction between the leftmost portion of the footprint (along the X-axis) and the rightmost portion of the footprint (along the X-axis). The length L may refer to the total separation along the Y-direction between the uppermost portion of the footprint (along the Y-axis) and the lowermost portion of the footprint (along the Y-axis).

The width of each nanostructure 42 may be greater than 1 micron, greater than 3 microns, greater than 5 microns, greater than 10 microns, greater than 20 microns, greater than 50 microns, less than 1 micron, less than 3 microns, less than 5 microns, less than 10 microns, less than 20 microns, less than 50 microns, between 5 microns and 20 microns, etc. The length of each nanostructure 42 may be greater than 1 micron, greater than 3 microns, greater than 5 microns, greater than 10 microns, greater than 20 microns, greater than 50 microns, less than 1 micron, less than 3 microns, less than 5 microns, less than 10 microns, less than 20 microns, less than 50 microns, between 5 microns and 20 microns, etc.

The footprint of each pseudocircular nanostructure may be characterized by an aspect ratio. The aspect ratio may be equivalent to a ratio between the longer of the length and the width and the smaller of the length and the width. Each pseudocircular nanostructure may have an aspect ratio that is greater than or equal to 1:1 and less than 2:1, less than 1.5:1, less than 1.2:1, less than 1.1:1, etc.

Said another way, each nanostructure 42 may have a geometric center. Each point may be at a distance from the geometric center. The distance from the geometric center to the furthest point on the perimeter from the geometric center may be no more than 50% greater than the distance from the geometric center to the closest point on the perimeter to the geometric center, the distance from the geometric center to the furthest point on the perimeter from the geometric center may be no more than double the distance from the geometric center to the closest point on the perimeter to the geometric center, the distance from the geometric center to the furthest point on the perimeter from the geometric center may be no more than triple the distance from the geometric center to the closest point on the perimeter to the geometric center, etc.

The shapes and dimensions of nanostructures 42 (e.g., the footprint shapes, widths, lengths, heights, sidewall angles, etc.) may be randomized to mitigate periodicity (and therefore mitigate diffractive artifacts in light 34 that passes through display cover layer 32). The randomized shapes and dimensions of nanostructures 42 may result in the display cover layer including a plurality of nanostructures with unique footprints (e.g., at least 10 nanostructures with unique footprints, at least 50 nanostructures with unique footprints, at least 100 nanostructures with unique footprints, at least 1000 nanostructures with unique footprints, etc.).

The nanostructures of FIGS. 4-6 may diffuse or scatter light reflected from upper surface 32-U, thereby reducing glare on upper surface 32-U of display cover layer 32. A reflected image from display cover layer 32 with nanostructures 42 may have a coherency less than that of a display cover layer without the nanostructures. The nanostructures 42 may also maintain the distinctness of image (DOI) of the light from display panel at a satisfactory level. In other words, nanostructures 42 may have optimized optical properties. However, in some cases it may be desirable to improve the mechanical properties of display cover layer 32.

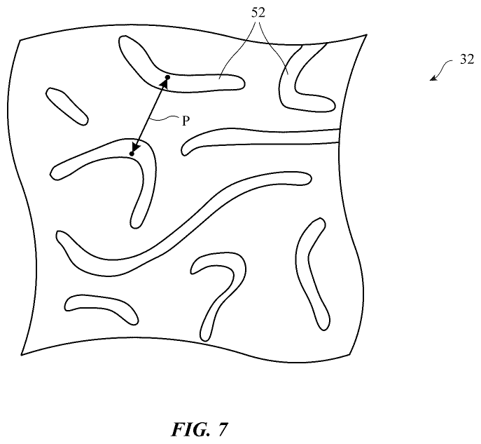

FIG. 7 is a top view of an illustrative display cover layer with nanostructures that improve the mechanical properties of display cover layer 32. As shown, display cover layer 32 may include nanostructures 52 (sometimes referred to as protrusions 52, surface features 52, etc.). Nanostructures 52 may have footprints that are elongated. These types of nanostructures may be referred to as elongated nanostructures 52, serpentine nanostructures, etc.

As shown in FIG. 7, adjacent nanostructures 52 may be separated by a center-to-center pitch P. Pitch P may be equivalent to the distance between the geometric centers of adjacent nanostructures. The magnitude of pitch P may be, on average, greater than 1 micron, greater than 3 microns, greater than 5 microns, greater than 10 microns, greater than 20 microns, greater than 50 microns, greater than 60 microns, greater than 70 microns, greater than 100 microns, less than 1 micron, less than 3 microns, less than 5 microns, less than 10 microns, less than 20 microns, less than 50 microns, less than 60 microns, less than 70 microns, less than 100 microns, between 20 microns and 100 microns, etc. Each given pitch between adjacent nanostructures may also be greater than 1 micron, greater than 3 microns, greater than 5 microns, greater than 10 microns, greater than 20 microns, greater than 50 microns, greater than 60 microns, greater than 70 microns, greater than 100 microns, less than 1 micron, less than 3 microns, less than 5 microns, less than 10 microns, less than 20 microns, less than 50 microns, less than 60 microns, less than 70 microns, less than 100 microns, between 20 microns and 100 microns, etc.

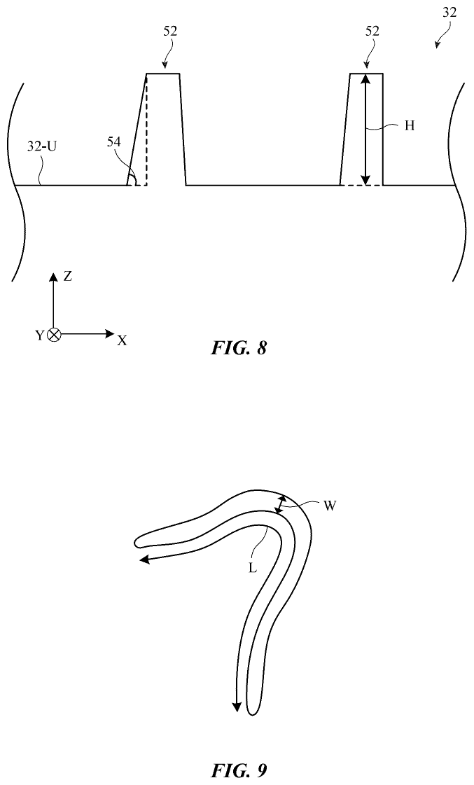

FIG. 8 is a cross-sectional side view of the display cover layer of FIG. 7. In FIG. 8, nanostructures 52 are formed from protrusions. The upper surface 32-U has a plurality of protruding portions to define a non-linear nanotextured surface. This example is merely illustrative and it should be understood that nanostructures 52 may also include recessed portions (sometimes referred to as depressions, craters, etc.) in display cover layer 32.

As shown in the cross-sectional side view of FIG. 8, the sloped sidewalls of each nanostructure 52 may be at an angle 54 relative to the XY-plane. In general, the sloped sidewalls may have any desired angle(s) and the angle(s) may vary as a function of position in the X-direction and/or Y-direction. Angle 54 may be equal to 90 degrees, less than 90 degrees, less than 85 degrees, less than 80 degrees, less than 70 degrees, greater than 70 degrees, greater than 80 degrees, greater than 85 degrees, etc.

FIG. 8 also shows how each nanostructure may have a corresponding height H. The height of each nanostructure 52 may be at least 50 nanometers, at least 100 nanometers, at least 200 nanometers, at least 500 nanometers, at least 1 micron, at least 2 microns, less than 50 nanometers, less than 100 nanometers, less than 200 nanometers, less than 500 nanometers, less than 1 micron, less than 2 microns, between 200 nanometers and 1 micron, etc.

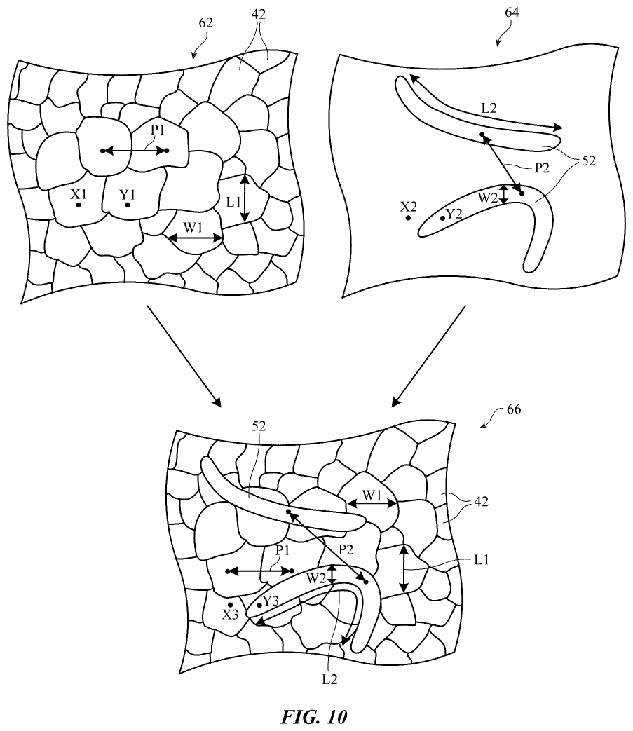

As shown in FIGS. 7 and 8, the nanostructures 52 may have irregular footprints. FIG. 9 is a top view of an illustrative elongated nanostructure with an irregular footprint. The footprint may be characterized by a width W and a length L. The length may refer to the total length of the nanostructure along the elongated path of the nanostructure. The width may refer to the maximum width of the nanostructure in a direction that is orthogonal to the length at any position along the elongated path of the nanostructure. The length is therefore always greater than the width.

The width of each nanostructure 52 may be greater than 10 nanometers, greater than 50 nanometers, greater than 100 nanometers, greater than 500 nanometers, greater than 1 micron, greater than 3 microns, greater than 5 microns, greater than 10 microns, greater than 20 microns, greater than 50 microns, less than 10 nanometers, less than 50 nanometers, less than 100 nanometers, less than 500 nanometers, less than 1 micron, less than 3 microns, less than 5 microns, less than 10 microns, less than 20 microns, less than 50 microns, etc. The length of each nanostructure 52 may be greater than 1 micron, greater than 3 microns, greater than 5 microns, greater than 10 microns, greater than 20 microns, greater than 50 microns, greater than 100 microns, greater than 200 microns, less than 1 micron, less than 3 microns, less than 5 microns, less than 10 microns, less than 20 microns, less than 50 microns, less than 100 microns, less than 200 microns, etc.

The footprint of each elongated nanostructure 52 may be characterized by an aspect ratio. The aspect ratio may be equivalent to a ratio between the length and the width. Each elongated nanostructure may have an aspect ratio that is greater than 2:1, greater than 4:1, greater than 6:1, greater than 10:1, greater than 20:1, greater than 30:1, etc. The average aspect ratio of the elongated nanostructures may be greater than 2:1, greater than 4:1, greater than 6:1, greater than 10:1, greater than 20:1, greater than 30:1, etc.

The ratio of height H to width W for each elongated nanostructure 52 may be greater than 2:1, greater than 4:1, greater than 6:1, greater than 10:1, greater than 20:1, greater than 30:1, etc. The average ratio of height H to width W for elongated nanostructures 52 may be greater than 2:1, greater than 4:1, greater than 6:1, greater than 10:1, greater than 20:1, greater than 30:1, etc.

The shapes and dimensions of nanostructures 52 (e.g., the footprint shapes, heights, widths, lengths, sidewall angles, etc.) may be randomized to mitigate periodicity (and therefore mitigate diffractive artifacts in light 34 that passes through display cover layer 32). The randomized shapes and dimensions of nanostructures 52 may result in the display cover layer including a plurality of nanostructures with unique footprints (e.g., at least 10 nanostructures with unique footprints, at least 50 nanostructures with unique footprints, at least 100 nanostructures with unique footprints, at least 1000 nanostructures with unique footprints, etc.).

The footprints of elongated nanostructures 52 may have one or more curves and may be referred to as serpentine footprints, winding footprints, meandering footprints, twisted footprints, tortuous footprints, sinuous footprints, etc.

The display cover layer of FIGS. 7-9 with elongated nanostructures 52 may have improved mechanical properties compared to the display cover layer of FIGS. 4-6 with pseudocircular nanostructures. However, the display cover layer of FIGS. 4-6 with pseudocircular nanostructures may have improved optical properties compared to the display cover layer of FIGS. 7-9 with elongated nanostructures 52. To form a display cover layer with both target optical performance and target mechanical performance, the upper surface 32-U of display cover layer 32 may have a combination of both pseudocircular nanostructures 42 and elongated nanostructures 52.

In particular, the nanotexture pattern of FIG. 4 (with pseudocircular nanostructures 42) may be combined with the nanotexture pattern of FIG. 7 (with elongated nanostructures 52) to form a hybrid nanotexture pattern with both pseudocircular nanostructures 42 and elongated nanostructures 52. FIG. 10 is a diagram showing this type of combination.

FIG. 10 shows a first nanotexture layout 62 that includes a plurality of pseudocircular nanostructures 42 similar to as shown in FIGS. 4-6 and a second nanotexture layout 64 that includes a plurality of elongated nanostructures 52 similar to as shown in FIGS. 7-9. Layouts 62 and 64 may be combined to form a single hybrid layout 66 that includes both pseudocircular nanostructures 42 and elongated nanostructures 52.

Combining layouts 62 and 64 to form a single hybrid layout may include adding the nanotexture of layout 62 to the nanotexture of layout 64, multiplying the nanotexture of layout 62 by the nanotexture of layout 64, or combining the nanotexture of layout 62 with the nanotexture of layout 64 using any desired non-linear operation.

Consider the examples of given points X1, X2, and X3 in layouts 62, 64, and 66. In layout 62, the nanotexture may have a first height H_X1 at point X1. In layout 64, the nanotexture may have a second height H_X2 at point X2. In layout 66, the nanotexture may have a third height H_X3 at point X3. Points X1, X2, and X3 may be at the same relative position within the layout. When layouts 62 and 64 are combined using addition to form hybrid layout 66, the height at point X3 may be equal to the sum of the heights at points X1 and X2 (e.g., H_X3=H_X1+H_X2). When layouts 62 and 64 are combined using multiplication to form hybrid layout 66, the height at point X3 may be equal to the product of the heights at points X1 and X2 (e.g., H_X3=H_X1×H_X2). It is noted that the magnitude of height used for these operations may be relative to a baseline at the lowest point on the upper surface of the display cover layer in the Z-direction.

Consider the examples of given points Y1, Y2, and Y3 in layouts 62, 64, and 66. In layout 62, the nanotexture may have a first height H_Y1 at point Y1. In layout 64, the nanotexture may have a second height H_Y2 at point Y2. In layout 66, the nanotexture may have a third height H_Y3 at point Y3. Points Y1, Y2, and Y3 may be at the same relative position within the layout. When layouts 62 and 64 are combined using addition to form hybrid layout 66, the height at point Y3 may be equal to the sum of the heights at points Y1 and Y2 (e.g., H_Y3=H_Y1+H_Y2). When layouts 62 and 64 are combined using multiplication to form hybrid layout 66, the height at point Y3 may be equal to the product of the heights at points Y1 and Y2 (e.g., H_Y3=H_Y1×H_Y2).

As a specific example, H_X1 may be equal to 150 nanometers, H_Y1 may be equal to 140 nanometers, H_X2 may be equal to 0 nanometers, and H_Y2 may be equal to 750 nanometers. In the example where the layouts are combined using addition, H_X3 is equal to 150 nanometers (150+0=150) and H_Y3 is equal to 890 nanometers (140+750=890).

Combining layout 62 (with nanostructures selected to optimize for optical performance) and layout 64 (with nanostructures selected to optimize for mechanical performance) may produce a nanotexture layout 66 with both excellent optical and mechanical properties.

The scale of nanostructures 52 relative to nanostructures 42 may be adjusted to tune the overall performance of display cover layer 32. In general, the height and length of nanostructures 52 in layout 64 may be greater than the height and length of nanostructures 42 in layout 62. This may result in nanostructures 52 dominating the hybrid layout when there is overlap between nanostructures 42 and nanostructures 52.

The average center-to-center pitch P1 between adjacent nanostructures 42 may be less than the average center-to-center pitch P2 between adjacent nanostructures 52. In particular, P2 may be greater than P1 by at least 10%, at least 30%, at least 50%, at least 100%, at least 200%, at least 300%, at least 500%, at least 1000%, etc. In other words, the spatial frequency of the nanostructures of different types is different. Said another way, the density of nanostructures 42 (e.g., the number of nanostructures 42 per unit area) may be different than the density of nanostructures 52 (e.g., the number of nanostructures 52 per unit area). In particular, the density of nanostructures 42 may be greater than the density of nanostructures 52 by at least 10%, at least 30%, at least 50%, at least 100%, at least 200%, at least 300%, at least 500%, at least 1000%, etc.

The average length L1 of nanostructures 42 may be less than the average length L2 of nanostructures 52. In particular, L2 may be greater than L1 by at least 50%, at least 100%, at least 200%, at least 300%, at least 500%, at least 1000%, at least 5000%, etc. The average length W1 of nanostructures 42 may be greater than, less than, or equal to the average width W2 of nanostructures 52. In particular, W2 may be greater than W1 by at least 5%, at least 10%, at least 20%, at least 30%, at least 50%, at least 100%, etc. Alternatively, W1 may be greater than W2 by at least 5%, at least 10%, at least 20%, at least 30%, at least 50%, at least 100%, etc.

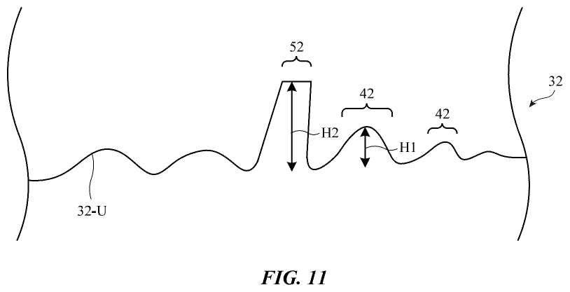

A cross-sectional side view of a display cover layer 32 having an upper surface 32-U with the hybrid layout 66 of FIG. 10 is shown in FIG. 11. As shown in FIG. 11, upper surface 32-U includes both pseudocircular nanostructures 42 and elongated nanostructures 52. The average height H1 of nanostructures 42 may be less than the average height H2 of nanostructures 52. In particular, H2 may be greater than H1 by at least 10%, at least 30%, at least 50%, at least 100%, at least 200%, at least 300%, at least 500%, at least 1000%, etc. The height H2 of elongated nanostructures 52 may vary across the length of the elongated nanostructure due to the combined topology from the pseudocircular nanostructures.

It is reiterated that any the above nanostructures may be included in a plastic display cover layer, glass display cover layer, sapphire display cover layer, or a display cover layer of any other desired material.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a display cover layer; and
display pixels that emit light through the display cover layer, wherein the display cover layer has an upper surface and wherein the upper surface comprises:
first protrusions of a first type, wherein the first protrusions have a first spatial frequency; and
second protrusions of a second type that is different than the first type, wherein the second protrusions have a second spatial frequency that is different than the first spatial frequency.

2. The electronic device defined in claim 1, wherein the first protrusions of the first type have a first average height, wherein the second protrusions of the second type have a second average height, and wherein the second average height is different than the first average height.

3. The electronic device defined in claim 2, wherein the second average height is at least 50% greater than the first average height.

4. The electronic device defined in claim 3, wherein adjacent first protrusions have a first average center-to-center pitch, wherein adjacent second protrusions have a second average center-to-center pitch, and wherein the second average center-to-center pitch is different than the first average center-to-center pitch.

5. The electronic device defined in claim 4, wherein the second average center-to-center pitch is at least 50% greater than the first average center-to-center pitch.

6. The electronic device defined in claim 5, wherein the first protrusions of the first type have a first average length, wherein the second protrusions of the second type have a second average length, and wherein the second average length is different than the first average length.

7. The electronic device defined in claim 6, wherein the second average length is at least 5 times greater than the first average length.

8. The electronic device defined in claim 1, wherein each one of the first protrusions of the first type has a respective aspect ratio that is less than 2:1 and wherein each one of the first protrusions of the first type has a respective aspect ratio that is greater than 4:1.

9. The electronic device defined in claim 8, wherein the second protrusions of the second type follow serpentine paths.

10. The electronic device defined in claim 1, wherein the display cover layer comprises glass.

11. The electronic device defined in claim 1, wherein the first protrusions of the first type comprise at least 50 protrusions with respective unique footprints.

12. The electronic device defined in claim 1, wherein the second protrusions of the second type comprise at least 50 protrusions with respective unique footprints.

13. An electronic device, comprising:
a glass layer; and
display pixels that emit light through the glass layer, wherein the glass layer has an upper surface with a first plurality of surface features each having a respective aspect ratio that is less than 2:1 and a second plurality of surface features each having a respective aspect ratio that is greater than 4:1.

14. The electronic device defined in claim 13, wherein each one of the first plurality of surface features has a respective height that is less than 200 nanometers and wherein each one of the second plurality of surface features has a respective height that is greater than 200 nanometers and less than 1 micron.

15. The electronic device defined in claim 14, wherein each adjacent pair of the first plurality of surface features has a respective center-to-center pitch that is less than 20 microns and wherein each adjacent pair of the second plurality of surface features has a respective center-to-center pitch that is greater than 20 microns and less than 100 microns.

16. The electronic device defined in claim 15, wherein the first plurality of surface features has a first number of surface features per unit area, wherein the second plurality of surface features has a second number of surface features per unit area, and wherein the first number of surface features per unit area is greater than the second number of surface features per unit area.

17. The electronic device defined in claim 13, wherein the second plurality of surface features comprises elongated surface features that follow serpentine paths.

18. A transparent layer having first and second opposing sides, the transparent layer comprising:
a first plurality of protrusions on the first side, wherein each one of the first plurality of protrusions has a respective height that is less than 200 nanometers; and
a second plurality of protrusions on the first side, wherein each one of the second plurality of protrusions has a respective height that is between 200 nanometers and 1 micron.

19. The transparent layer defined in claim 18, wherein the first plurality of protrusions has a higher spatial frequency than the second plurality of protrusions.

20. The transparent layer defined in claim 18, wherein each one of the first plurality of protrusions has a respective footprint with an aspect ratio that is less than 2:1 and wherein each one of the second plurality of protrusions has a respective footprint with an aspect ratio that is greater than 4:1.

21. The transparent layer of claim 18, wherein the transparent layer is a glass layer.

22. The transparent layer of claim 18, wherein the transparent layer is a plastic layer.
